(19) United States
(12) Patent Application Publication
(10) Pub. No.: US 2024/0105468 A1
(43) Pub. Date: Mar. 28, 2024

(54) POWER MODULE FOR OPERATING AN ELECTRIC VEHICLE DRIVE HAVING OPTIMIZED COOLING AND CONTACTING

(71) Applicant: ZF Friedrichshafen AG, Friedrichshafen (DE)

(72) Inventors: Michael FÜGL, Neumarkt i. d. Opf. (DE); Torsten SCHELLER, Königstein (DE); Michael LORENZ, Tettau (DE); Sigrid ZISCHLER, Feucht (DE)

(73) Assignee: ZF Friedrichshafen AG, Friedrichshafen (DE)

(21) Appl. No.: 18/257,795

(22) PCT Filed: Dec. 8, 2021
(86) PCT No.: PCT/EP2021/084787

§ 371 Date: Jun. 15, 2023

(30) Foreign Application Priority Data
Dec. 18, 2020 (DE) 10 2020 216 315.4

(51) Int. Cl. H01L 21/48; H01L 23/36; H01L 23/498

(52) U.S. Cl. CPC H01L 21/4857; H01L 23/36; H01L 23/49822; H01L 24/48; H01L 2224/48225

(57) ABSTRACT

The invention relates to a method for producing a power module, comprising: providing an insulating substrate, composed of a first metal layer, a second metal layer, and an insulating layer placed between the first metal layer and second metal layer; formation of numerous contact wires located on a first side of the insulating substrate facing away from the second metal layer and on a second side of the insulating substrate facing away from the first metal layer; applying an electrically conductive layer to the first side, which comes in contact with numerous power switches, and applying a heatsink to the second side.

### TECHNOLOGICAL FIELD

The present invention relates to the field of electric mobility, in particular the power module for operating an electric drive for a vehicle.

### TECHNOLOGICAL BACKGROUND

Power modules, in particular integrated power modules, are increasingly being used in motor vehicles. These power modules are used in DC/AC power inverters, for example, in order to supply electric motors with multiphase alternating current. This involves converting a direct current from a DC power source such as a battery into a multiphase alternating current. Other fields of application also include DC/DC converters and AC/DC rectifiers (converters). These power modules comprise semiconductors, in particular transistors in the form of IGBTs, MOSFETs, and HEMTs.

With high current applications, e.g. 400V or 800V applications, a corresponding amount of heat is generated in the power modules. This heat must be discharged to prevent overheating in the power switches, which would have a negative impact on the performance of the power module, or power inverter. A heatsink is used in the power module for this, which is coupled thermally to the power switch.

Discrete semiconductor packages that have a nonconductive rear surface have been used in the prior art. These semiconductor packages must be attached to the heatsink such that they are electrically insulated. This often requires an additional thermal interface material (TIM). This results in an extremely limited thermal conductance between the electronic components and the heatsink in the power module, resulting in high thermal resistances.

The fundamental object of the invention is therefore to reduce the thermal resistances in the power module while also simplifying production.

These problems are solved with a method for producing a power module and such a power module, as well as its use in a vehicle, according to the independent claims.

The power module in the framework of this invention is used to operate an electric drive in a vehicle, in particular an electric vehicle and/or hybrid vehicle. The power module is preferably used in a DC/AC power inverter. Other uses include DC/DC converters and AC/DC rectifiers (converters). In particular, the power module is used to supply power to an electric machine, e.g. an electric motor and/or generator. A DC/AC power inverter is used to generate a multiphase alternating current from a direct current generated by a DC voltage from an energy source such as a battery.

The input current (direct current) is preferably obtained from an input contact to a positive pole and a negative pole. When the power module is in operation, the positive pole is connected to a positive connection on the battery, and the negative pole is connected to a negative connection on the battery.

The power module also has numerous power switches connected in parallel to a damping capacitor. These semiconductor power switches are used to generate an output current from the input current through activation of the individual power switches.

The power switches can be activated with a pulse-width modulation. The output current can be output to a load, i.e. an electric machine, at an output contact on the power module.

The power switches preferably form a bridge circuit assembly. The bridge circuit assembly can comprise one or more bridge circuits, each of which forms a half bridge. Each half bridge comprises a high-side switch (HS switch) and a low-side switch (LS switch) that is connected in series to the high-side switch. Each half bridge is assigned a current phase of a multiphase alternating current (output current). The HS switch and/or LS switch comprise one or more power semiconductors, e.g. IGBTs, MOSFETs, or HEMTs. The fundamental material for the HS and LS switches preferably comprises a so-called wide-bandgap semiconductor (a semiconductor with a wide bandgap), such as silicon carbide (SiC) or gallium nitride (GaN).

The power module also has an insulating substrate, comprising a first metal layer, second metal layer, and an insulating layer between the two metal layers. The first and/or second metal layers can contain copper or a copper alloy. The insulating layer contains an insulating material such as a polyimide. The first and/or second metal layers are preferably applied to the insulating layer in a coating process. The insulating substrate has a first side and a second side, which faces away from the first side with respect to the direction in which the coating is applied. The first side is preferably the upper surface for the first metal layer, and the second side is preferably the lower surface for the second metal layer. An electrically conductive layer that can be brought into contact with the numerous power switches is applied to the first side. A heat sink for discharging the heat generated by the power switches and other electric and electronic components in the power module is applied to the second side.

According to the invention, numerous contact wires are formed, which are located on the first side and second side of the insulating substrate. The contact wires are made of an electrically conductive material such as metal, semimetal, or a semiconductor. The contact wires are preferably formed with a lithography process. The contact wires preferably form nanowires, which are perpendicular to the first and second sides of the insulating substrate. The contact wires are preferably approximately as long as the thicknesses of the first and second metal layers.

The distance between the electric components (e.g. power switches) and the heatsink is preferably reduced through the use of the contact wires. Consequently, there is no need for a thermal interface material (TIM). The thermal resistance in the power module is therefore reduced, resulting in an improved heat discharge and cooling of the power module.

Advantageous designs and further developments are described in the dependent claims.

Exemplary embodiments of the invention shall be described in reference to the attached drawings. Therein:

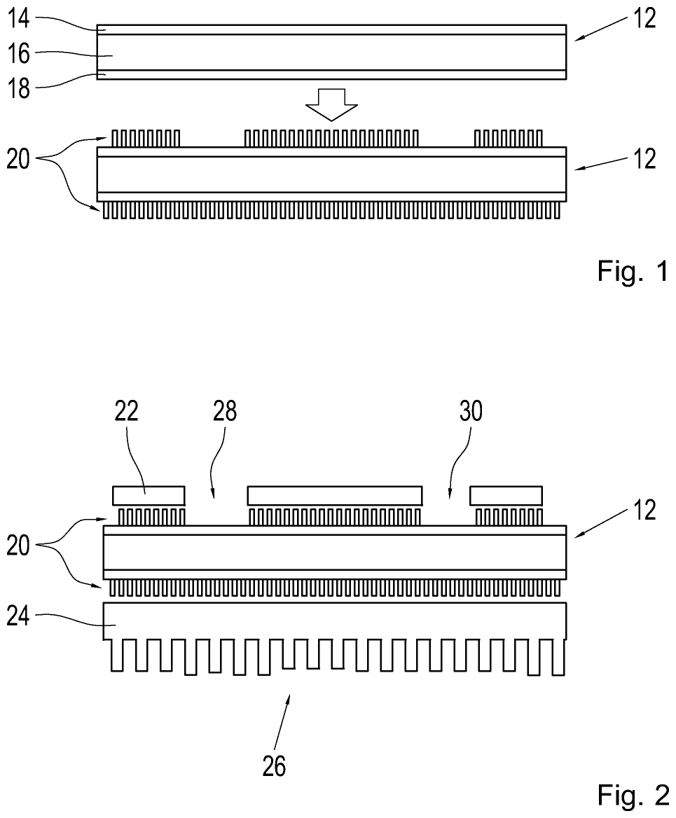

FIGS. 1-4 show schematic illustrations of a method for producing a power module.

The same reference symbols are used in the various drawings for identical or functionally similar parts. The relevant parts are indicated with reference symbols in the individual figures.

FIGS. 1-4 show schematic drawings illustrating a method for producing a power module. First, an insulating layer 12 is obtained, comprising a first metal layer 14, second metal layer 18, and an insulating layer 16 placed therebetween. The first and/or second metal layers 14, 18 are preferably made of copper or a copper alloy. The insulating layer 16 is preferably made of an insulating material such as a polyimide. As FIG. 1 shows, the insulating layer 12 has a first side (upper surface) and a second side (lower surface). Numerous contact wires 20 are placed on the first and second sides. The contact wires 20 are made of an electrically conductive material such as a metal, semimetal, and/or a semiconductor (e.g. a compound semiconductor). The contact wires 20 form nanowires that are substantially perpendicular to the first and second sides. The lengths of the nanowires are approximately equal to the thicknesses of the first and second sides 14, 18.

The nanowires are preferably formed with a lithography process. A shadow mask is used in order to clear specific regions in a template material, thus determining the positions of the nanowires 20. As shown in FIG. 2, in order to electrically insulate different sections of nano wires 20, larger areas 28, 30 are cleared of nanowires. A galvanizing process can be subsequently carried out.

After the contact wires 20 have been formed, an electrically conductive layer 22 is applied to the first side (upper surface) of the insulating substrate 12. A heatsink 24 comprising a pin-fin structure 26 is also applied to the second side (lower surface) of the insulating substrate 12. Instead of the pin-fin structure 26, the heatsink can exhibit another cooling structure such as cooling channels, cooling trenches, etc. For a better thermal coupling, an oxide layer on the contact surface of the heatsink 24 facing the insulating substrate 12 is removed before connecting it to the insulating substrate 12.

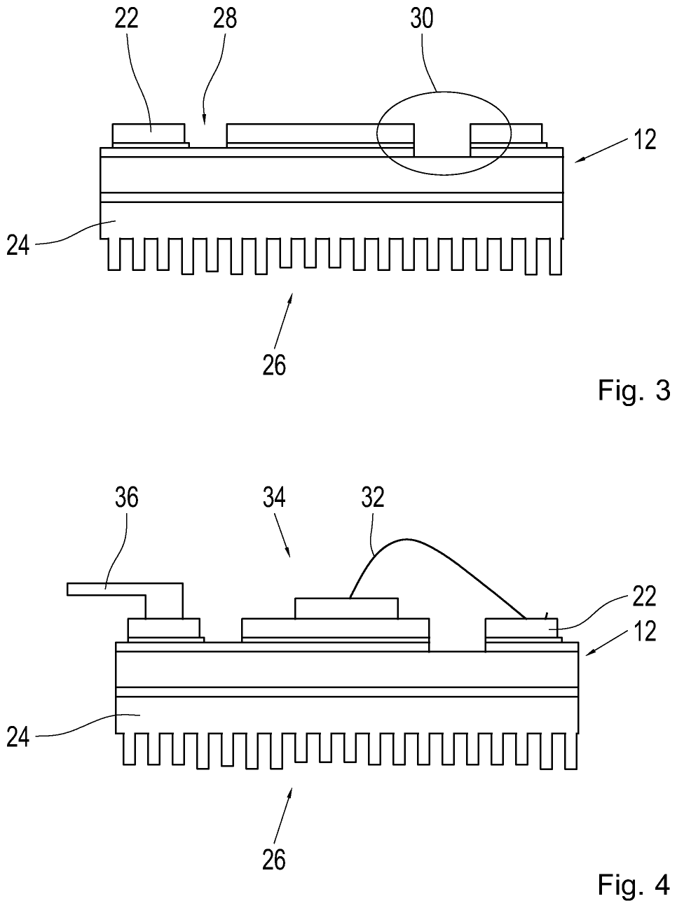

As shown in FIGS. 2-3, certain regions in the electrically conductive layer 22 that are brought in contact with the power switches 34 (e.g. IGBTs), wire bonds 32, and lead frames 36, are at least partially cleared, corresponding to the cleared regions in the contact wires 20, in order to electrically insulate between various contacts for the components 32, 34, 36, and prevent short circuiting. The completed power module is shown schematically in FIG. 4.

### REFERENCE SYMBOLS

12 insulating substrate
14 first metal layer
16 insulating layer
18 second metal layer
20 contact wires
22 electrically conductive layer
24 heatsink
26 pin-fin structure
28, 30 cleared regions
32 wire bonding
34 power switch
36 lead frame

1. A method for producing a power module, comprising:
providing an insulating substrate comprising a first metal layer, a second metal layer, and an insulating layer placed between the first metal layer and second metal layer;
forming numerous contact wires located on a first side of the insulating substrate facing away from the second metal layer and on a second side of the insulating substrate facing away from the first metal layer; and
applying an electrically conductive layer to the first side, which comes in contact with numerous power switches, and applying a heatsink to the second side.

2. The method according to claim 1, wherein the contact wires are nanowires.

3. The method according to claim 1, comprising:
forming the contact wires using a lithography process in which a shadow mask is used to determine positions of the contact wires.

4. The method according to claim 1, comprising:
attaching the electrically conductive layer and the heat sink using a diffusion process.

5. The method according to claim 1, comprising:
arranging the contact wires differently on the first side than on the second side.

6. The method according to claim 1, wherein the first and/or second sides have cleared regions in which there are no contact wires.

7. The method according to claim 6, wherein the cleared regions are generated using a mechanical, chemical, and/or laser process.

8. A power module for operating an electric vehicle drive, comprising:
an insulating substrate comprising a first metal layer, a second metal layer, and an insulating layer placed between the first metal layer and second metal layer;
numerous contact wires located on a first side of the insulating substrate facing away from the second metal layer and on a second side of the insulating substrate facing away from the first metal layer;
an electrically conductive layer applied to the first side, which comes in contact with numerous power switches; and
a heatsink applied to the second side.

9. The power module according to claim 8, wherein the contact wires are nanowires.

10. The power module according to claim 8, wherein the contact wires are formed using a lithography process in which a shadow mask is used to determine positions of the contact wires.

11. The power module according to claim 8, wherein the electrically conductive layer and the heat sink are attached using a diffusion process.

12. The power module according to claim 8, wherein the contact wires are arranged differently on the first side than on the second side.

13. The power module according to claim 8, wherein the first and/or second sides have cleared regions in which there are no contact wires.

14. The power module according to claim 13, wherein the cleared regions are generated using a mechanical, chemical, and/or laser process.
